(19) United States
(12) Patent Application Publication
(10) Pub. No.: US 2009/0240996 A1
(43) Pub. Date: Sep. 24, 2009

(54) SEMICONDUCTOR INTEGRATED CIRCUIT DEVICE

(75) Inventors: Hiroyuki Sasaya, Tokyo (JP); Nobukazu Yabumoto, Itami Hyogo-ken (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/401,751

(22) Filed: Mar. 11, 2009

(30) Foreign Application Priority Data
Mar. 12, 2008 (JP) 2008-062131

(51) Int. Cl. G01R 31/3177; G06F 11/25

(52) U.S. Cl. 714/729; 714/E11.155

(57) ABSTRACT

A semiconductor integrated circuit equipped with multiple serially coupled scan chains which are used to shift inspection data based on different clock signals in order to inspect a scan path is provided. Inspection data is supplied to the respective scan chains in a first inspection mode, and the inspection data is supplied to the first stages of scan chains when in a second inspection mode. The inspection data supplied to the serially coupled scan chains in the second inspection mode is held in sequence by data hold units while being shifted between the scan chains.

### CROSS-REFERENCE TO RELATED APPLICATIONS

This patent application claims priority from Japanese Patent Application No. 2008-062131, filed Mar. 12, 2008, the entirety of which is incorporated herein by reference.

### FIELD OF THE INVENTION

The present invention pertains to a semiconductor integrated circuit capable of inspecting a logic circuit utilizing a scan path method.

### BACKGROUND

Due to larger scale circuits and more complicated functions, Large Scale Integrations or LSIs have become more difficult to inspect in recent years, and a variety of inspection methods are developed accordingly. Scan path is known as a technique for LSI inspection utilizing circuit controllability and observability. In LSI circuits utilizing the scan path method, logic circuits are configured using flop-flops referred to as scan registers. The respective scan registers function as ordinary flip-flops during normal operation, but they function as one or more series of shift registers which are coupled in the form of chains when switched to an inspection mode. Shift registers formed using the scan registers are also referred to as scan chains.

With the scan path method, the inspection mode and the normal operating mode are switched using a control signal in order to observe LSI behavior. In general, inspection data are first input serially from an inspection device to the scan chains when in the inspection mode in order to set inspection data with desired values at the respective scan registers. Next, normal operation is executed for an arbitrary number of clock cycles, and data output from a logic circuit are held by the respective scan registers. Subsequently, upon returning the inspection mode again, the data held by the scan chains are shifted serially and taken into the inspection device. The inspection device carries out analyses by comparing the inspection data input with data which are obtained as a response to it in order to determine whether the LSI is executing prescribed operations.

FIG. 7 is a diagram showing an example configuration of a popular LSI whose logic circuit is inspected using the scan path method, which is shown in Japanese Patent No. 3529762. LSI 100 has m clock domains which operate independently synchronously with respective clock signals (CK1-CKm), and a scan chain (120_1-120_{—}m) is formed for each clock domain. Decompressor 110 and compressor 130 are circuits used for inspecting a scan path which is formed inside of LSI 100, and it is provided for the purpose of reducing the amount of data transferred between LSI inspection device 200 and LSI 100 in order to reduce the inspection time. Decompressor 110 decompresses compressed inspection data Sin transferred from LSI inspection device 200 and serially inputs the data to the m scan chains 120_1-120_{—}m. Compressor 130 compresses the respective data which are serially output from the m scan chains 120_1-120_{—}m and sends them to LSI inspection device 200 as data Sout which correspond to inspection data Sin.

When multiple scan chains are involved, the inspection data is usually supplied to the individual scan chains using inspection circuits (110 and 130) which are provided inside of the LSI as shown in FIG. 7. On the other hand, in the event of a failure of decompressor 110 or compressor 130, it would be convenient if the inspection could be carried out without using these inspection circuits. For example, if multiple scan chains can be coupled in series to form a single scan chain, the inspection time becomes slower, but pass/fail judgment and failure analysis can be carried out without using decompressor 110 and compressor 130 in the LSI.

However, while it may be easy to configure a circuit for the clock signals such that clock frequencies of the respective clock domains match when in inspection mode, it is sometimes also difficult to match mismatched phases of the clock signals accurately. When multiple scan chains with different clock signal phases are coupled in series, erroneous shifting of data takes place between the scan chains. In other words, if data are shifted when the phases of the clock signals are mismatched, it creates the problem of missing portions in the data which are supposed to be transferred serially or the problem of a data order which does not match the clock cycles.

### SUMMARY

The semiconductor integrated circuit pertaining to a preferred embodiment of the present invention has multiple scan chains, an inspection data supply unit, and a data hold unit. The scan chains shift inspection data based on respective corresponding clock signals. Phases of the respective clock signals for the respective scan chains are somewhat shifted from each other. The inspection data supply unit supplies the inspection data to the respective multiple scan chains when in a first inspection mode and connects the multiple scan chains in series to form a single chain when in a second inspection mode in order to supply the inspection data to the first-stage scan chain. The data hold unit holds the inspection data being shifted between the scan chains in sequence such that the inspection data supplied to the scan chains coupled in series are shifted in sequence across the scan chains according to the sequence of the clock cycles of the clock signals.

The multiple scan chains are coupled in series by the inspection data supply unit in order to supply the inspection data to its first-stage scan chain when in the second inspection mode. The inspection data supplied are shifted through the respective scan chains based on clock signals with different phases. Here, the data are held by the data hold unit when they are shifted between directly coupled scan chains. That is, the inspection data are held in sequence by the data hold unit while they are being shifted between the directly coupled scan chains such that they are shifted in sequence across the scan chains according to the sequence the clock cycles of the clock signals.

Preferably, the semiconductor integrated circuit is equipped with a response data processing unit which is used to process respective response data which are input from the multiple scan chains without involving the data hold unit when in the first inspection mode.

When the response data are transmitted through the data hold unit, 1 response datum is held by the data hold unit at some point within 1 clock cycle during which the 1 response datum is output from the scan chains. In this case, because a setup time, which is set before the data are held by the data hold unit, becomes shorter than the 1 clock cycle, the room for the setup time at the data hold unit is reduced, resulting in a stricter timing requirement pertaining to the data hold operation by the data hold unit. On the other hand, according to the response data processing unit, because the response data from the scan chains are input to the response data processing unit without involving the data hold unit, the restriction imposed by the timing requirement is eliminated.

The data hold unit may include a latch circuit which is provided on the path where the multiple scan chains are coupled in series. The latch circuit may hold inspection data, which are output from the preceding-stage scan chain synchronously with the first edge of its clock signal, synchronously with the second edge of the clock signal and output the held inspection data to the subsequent-stage scan chain.

In this case, the response data processing unit may process the response data which are input from the multiple scan chains without involving the latch circuit.

In addition, the inspection data supply unit may include a selector circuit which is provided on a path which connects the multiple scan chains in series. The selector circuit may selectively output inspection data, which are generated pertaining to the subsequent-stage scan chain, when in the first inspection mode and selectively output inspection data input from the preceding-stage scan chain through the data hold unit when in the second inspection mode.

On the other hand, at the semiconductor integrated circuit, the data hold unit may output the inspection data transmissively when in the first inspection mode, and the response data processing unit may take response data input from some of the scan chains through the data hold unit.

According to the configuration, because the inspection data are output transmissively from the data hold unit when in the first inspection mode, the timing requirement at the data hold unit is not strict even when the response data are input to the response data processing unit through the data hold unit.

In this case, the data hold unit may include a latch circuit which is provided on the path where the multiple scan chains are coupled in series, for example. The latch circuit may hold the inspection data, which are output from the preceding-stage scan chain synchronously with the first edge of its clock signal, synchronously with the second edge of the clock signal and outputs the held inspection data to the subsequent-stage scan chain when in the second inspection mode and outputs the response data, which are output from the preceding-stage scan chain, transmissively to the subsequent-stage scan chain when in the first inspection mode.

In addition, in this case, the response data processing unit may take response data input from at least some of the scan chains through the latch circuit.

In addition, in the semiconductor integrated circuit, the data hold unit may output the inspection data transmissively when in the first inspection mode, and the inspection data supply unit may include a selector circuit which is provided on the input side of the data hold unit on the path which connects the multiple scan chains in series. The selector circuit may selectively output inspection data, which are generated pertaining to the subsequent-stage scan chain when in the first inspection mode and selectively output the inspection data which are input from the preceding-stage scan chain when in the second inspection mode. In this case, the response data processing unit may take the response data input from the multiple scan chains at the input side of the selector circuit.

The semiconductor integrated circuit in accordance with a preferred embodiment of the present invention includes a first serial data input terminal; a second serial data input terminal; a first scan chain which is equipped with multiple memory circuits coupled in series, of which the memory circuit of the first stage is coupled to the first serial data input terminal in order to transfer data from the first-stage memory circuit to the last-stage memory circuit in response to a first clock signal; a second scan chain which is equipped with multiple memory circuits coupled in series in order to transfer data from the first-stage memory circuit to the last-stage memory circuit in response to a second clock signal; a first data hold circuit which is coupled to the output terminal of the last-stage memory circuit of the first scan chain in order to hold data which are output from the last-stage memory circuit in response to the first clock signal; a second data hold circuit which is coupled to the output terminal of the last-stage memory circuit of the second scan chain in order to hold data which are output from the last-stage memory circuit in response to the second clock signal; and a first selector circuit, wherein its first input terminal is coupled to the serial data input terminal, its second input terminal is coupled to the output terminal of the first data hold circuit, and its output terminal is coupled to the input terminal of the first-stage memory circuit of the second scan chain, in order to output data which are supplied to the first input terminal or data which are supplied to the second input terminal through its output terminal in response to a control signal; wherein first and second inspection data are supplied in parallel to the first and the second scan chains, respectively, through the first and the second serial data input terminals when in the first inspection mode; and third inspection data are supplied serially to the first and the second scan chains, which are coupled in series through the first data hold circuit and the first selector circuit, through the first serial data input terminal when in the second inspection mode.

Preferably, in the semiconductor integrated circuit in accordance with a preferred embodiment of the present invention, the memory circuits of the first scan chain take in the inspection data in response to the first edge of the first clock signal, and the first data hold circuit takes in the inspection data in response to the second edge of the first clock signal second inspection mode when in the second inspection mode.

Also, preferably, in the semiconductor integrated circuit in accordance with a preferred embodiment of the present invention, frequencies of the first clock signal and the second clock signal are equalized when in the first and the second inspection modes.

According to the present invention, because the inspection data shifted between the scan chains are held at appropriate timing, the multiple scan chains, which are used to shift the inspection data based on the different clock signals, can be coupled in series in order to inspect the scan path.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram illustrating an example configuration of the semiconductor integrated circuit in accordance with a preferred embodiment of the present invention;

FIG. 2 is a diagram showing example operations carried out when phases of clock signals match if scan chains are coupled in series without a data hold unit;

FIG. 3 is a diagram showing example operations carried out when phases of clock signals are shifted from each other if scan chains are coupled in series without data hold unit;

FIG. 4 is a diagram for explaining operations carried out when data are shifted between scan chains via a data hold unit;

FIG. 5 is a diagram illustrating an example configuration of the semiconductor integrated circuit;

FIG. 6 is a diagram of the semiconductor integrated circuit in accordance with a preferred embodiment of the present invention; and

FIG. 7 is a diagram showing an example configuration of a conventional LSI whose logic circuit is inspected using a scan path method.

### DETAILED DESCRIPTION

Refer now to the drawings wherein depicted elements are, for the sake of clarity, not necessarily shown to scale and wherein like or similar elements are designated by the same reference numeral through the several views.

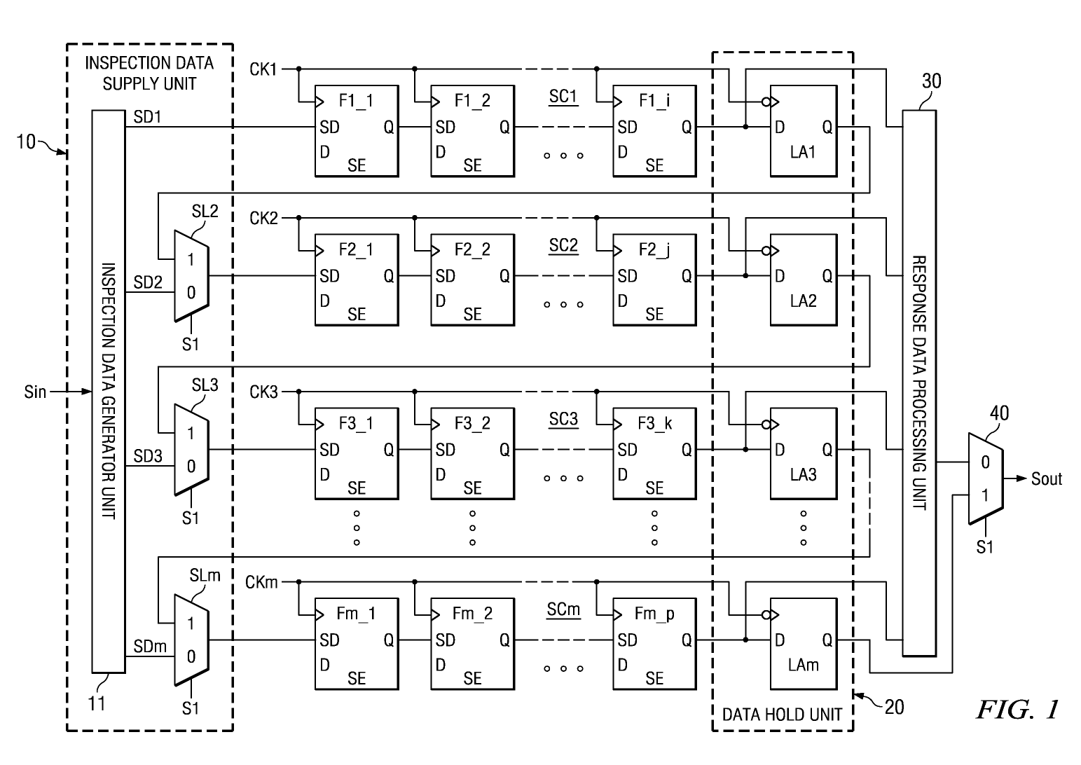

FIG. 1 is a diagram illustrating an example configuration of the semiconductor integrated circuit in accordance with a preferred embodiment of the present invention. The semiconductor integrated circuit shown in FIG. 1 has m units (m represents an integer greater than or equal to 2; as is also true below) of scan chains SC1-SCm, inspection data supply unit 10, data hold unit 20, response data processing unit 30, and selector circuit 40.

The semiconductor integrated circuit in accordance with a preferred embodiment of the present invention has 2 types of inspection modes. In the first inspection mode, independent inspection data are supplied to the m scan chains SC1-SCm. In the second inspection mode, the m units of scan chains SC1-SCm are coupled in series, and the inspection data are shifted through the scan chains. Scan chains SC1-SCm are formed using flip-flops that belong to different clock domains. Scan chain SCn (n represents an integer ranging from 1 to m; as is also true hereinafter) shifts the inspection data based on clock signal CKn.

Clock signals CK1-CKm have the same frequency at least when in the inspection modes. For example, the semiconductor integrated circuit shown in FIG. 1 is provided with a clock generator circuit (not shown), which is capable of changing the frequencies of clock signals CK1-CKm when in normal operating mode and when in the inspection modes; and the frequencies of clock signals CK1-CKm are all set to become the same when in the inspection modes using the clock generator circuit. However, while clock signals CK1-CKm may have the same frequency, they are not necessarily in-phase. Thus, when in the second mode where scan chains SC1-SCm are coupled in series, timing for shifting data between the scan chains is adjusted by data hold unit 20 (to be described below).

Scan chains SC1-SCm are formed respectively by coupling multiple flip-flops in series. In the example shown in FIG. 1, scan chain SC1 is configured by coupling i flip-flops FF1_1-FF1_{—}i in series. Scan chain SC2 is configured by coupling j flip-flops FF2_1-FF2_{—}j in series. Scan chain SC3 is configured by coupling k flip-flops FF3_1-FF3_{—}k in series. Scan chain SCm is configured by coupling p flip-flops FFm_1-FFm_{—}p in series. An arbitrary flip-flop used to configure scan chain SCn is denoted as “Fn” below.

As shown in FIG. 1, for example, flip-flop Fn is equipped with 2 input terminals SD and D and 1 output terminal Q. Input terminal D becomes effective when in the normal operating mode, and input terminal SD becomes effective when in the inspection modes. Flip-flop Fn enables either input terminal D or SD according to an enable signal input to control terminal SE. Flip-flop Fn holds a signal input to the effective input terminal (D or SD) synchronously with the rise of clock signal CKn and outputs it from output terminal Q.

As shown in FIG. 1, in scan chain SCn, output terminal Q of preceding-stage flip-flop Fn is coupled to input terminal SD of subsequent-stage flip-flop Fn. Also, although it is not illustrated, a logic circuit (for example, a combinational logic circuit) is provided between input terminal D and output terminal Q of each flip-flop, and a logic signal is sent to the circuit when in the normal operating mode. Inspection data supply unit 10 supplies the inspection data to scan chains SC1-SCm when in the respective inspection modes. That is, inspection data supply unit 10 supplies the inspection data to respective scan chains SC1-SCm when in the first inspection mode, and it connects scan chains SC1-SCm in series and supplies the inspection data to the first-stage scan SC1 chain when in the second inspection mode.

As shown in FIG. 1, for example, inspection data supply unit 10 has inspection data generator unit 11 and selector circuits SL2 through SLm. Inspection data generator unit 11 generates inspection data to be supplied to scan chains SC1-SCm. That is, inspection data generator unit 11 generates inspection data SD1-SDm to be supplied to m numbers of scan chains SC 1-SCm when in the first inspection mode, and it generates inspection data SD1 to be supplied to the first stage (scan chain SC1) of serially coupled scan chains SC1-SCm when in the second inspection mode. For example, when in the first inspection mode, inspection data generator unit 11 takes inspection data Sin compressed by an inspection device (not shown) as an external input to the semiconductor integrated circuit and restores (decompresses) them in order to generate inspection data SD1-SDm. In addition, when in the second inspection mode, inspection data generator unit 11 supplies inspection data Sin input from the external inspection device to first-stage scan chain SC1 as-is as inspection data SD1.

Selector circuits SL2 through SLm switch the inspection data input to scan chains SC2-SCm according to the given inspection mode type. For example, selector circuit SLq (q represents an integer ranging from 2 to m, as is also true hereinafter) is provided on the output side of data hold unit 20 on the path which connects scan chain SCq-1 to scan chain SCq. Selector circuit SLq selectively outputs inspection data SDq of scan chain SCq generated by inspection data generator unit 11 when in the first inspection mode and selectively outputs the inspection data input from scan chain SCq-1 through data hold unit 20 when in the second inspection mode. Selector circuit SLq selects one of the 2 inputs according to inspection mode control signal S1.

Data hold unit 20 holds the inspection data being shifted between the scan chains in sequence such that the inspection data supplied to scan chains SC 1-SCm, which are coupled in series in the second inspection mode, are shifted in sequence across the scan chains according to the sequence of the clock cycles of the clock signals (CK1-CKm). That is, data hold unit 20 holds the inspection data being shifted between the scan chains at the appropriate timing such that erroneous shifting of data between the scan chains due to a phase difference between the clock signals can be prevented. Data hold unit 20 adjusts the timing for shifting the inspection data between the scan chains in such a manner that the inspection data can be shifted correctly according to the sequence of the clock cycles even when the respective scan chains are operating synchronously with different clock signals. For example, data hold unit 20 holds inspection data, which are output synchronously with clock signal CKq-1 from the last stage of scan chain SCq-1, after clock signal CKq-1 with a delay of almost a half cycle before it outputs the data to the subsequent-stage scan chain SCq. As a result, the period during which the data output from scan chain SCq-1 can be taken in at the subsequent-stage scan chain SCq is extended to the extent of almost a half clock cycle. As a result, even when the phase of clock signal CKq lags that of clock signal CKq-1, the data can be shifted correctly from scan chain SCq-1 to scan chain SCq. In the example in FIG. 1, data hold unit 20 has latch circuits LA1-LAm.

Latch circuit LAr (r represents an integer ranging from 1 to m−1, as is also true hereinafter) is provided on the path which connects scan chain SCr to scan chain SCr+1 in series. Latch circuit LAr holds the inspection data, which are output synchronously with the rise (first edge) of the clock signal CKr from preceding-stage scan chain SCr, synchronously with the fall (second edge) of clock signal CKr and outputs the data to subsequent-stage scan chain SCr+1. Latch circuit LAm holds the inspection data, which are output from last-stage scan chain SCm, synchronously with the fall of clock signal CKm and outputs the data to selector circuit 40. Response data processing unit 30 processes m sets of response data which are output from scan chains SC1-SCm when in the first inspection mode. For example, response data processing unit 30 compresses these data and sends the data to an inspection device (not shown). As shown in FIG. 1, response data processing unit 30 takes in the response data from scan chains SC1-SCm without involving data hold unit 20 and processes them. As a result, the restriction imposed by the setup time, which would otherwise be required when holding the data from scan chains SC1-SCm at data hold unit 20, is eliminated, so that the data can be shifted across scan chains SC1-SCm more quickly in the first inspection mode.

Selector circuit 40 selectively outputs the response data processed by response data processing unit 30 when in the first inspection mode and selectively outputs the response data from serially coupled scan chains SC1-SCm when in the second inspection mode. Selector circuit 40 selects one of the 2 inputs according to inspection mode control signal S1. The response data selected by selector circuit 40 are output to the inspection device (not shown). Here, an example of the operations performed in the respective inspection modes by the semiconductor integrated circuit with the configuration shown in FIG. 1 will be explained.

In a first inspection mode, compressed inspection data Sin are generated by the inspection device (not shown) and input to inspection data generator unit 11. Compressed inspection data Sin are restored (decompressed) at inspection data generator unit 11 and expanded into inspection data SD1-SDm. Inspection data SD1 are input to scan chain SC1. Inspection data SDq (q=2-m) are input to scan chain SCq via selector circuit SLq. The flip-flops of the respective scan chains are set to the first inspection mode using an enable signal, whereby the inspection data input to scan chain SCn are shifted serially synchronously with the clock signal CKn. Once inspection data with desired values are set at the respective flip-flops, the flip-flops of the respective scan chains are first set to the normal operating mode, and the normal operation is carried out for the desired clock cycle duration. Subsequently, the flip-flop are brought back to the inspection mode, and the response data held at the respective flip-flops are shifted serially to response data processing unit 30. The response data from scan chains SC1-SCm are input to response data processing unit 30 without involving data hold unit 20. The m sets of response data are compressed into single response data Sout at response data processing unit 20. Compressed response data Sout are taken into the inspection device through selector circuit 40. The inspection data input and the response data taken in are compared at the inspection device in order to determine whether or not the semiconductor integrated circuit is performing desired operations.

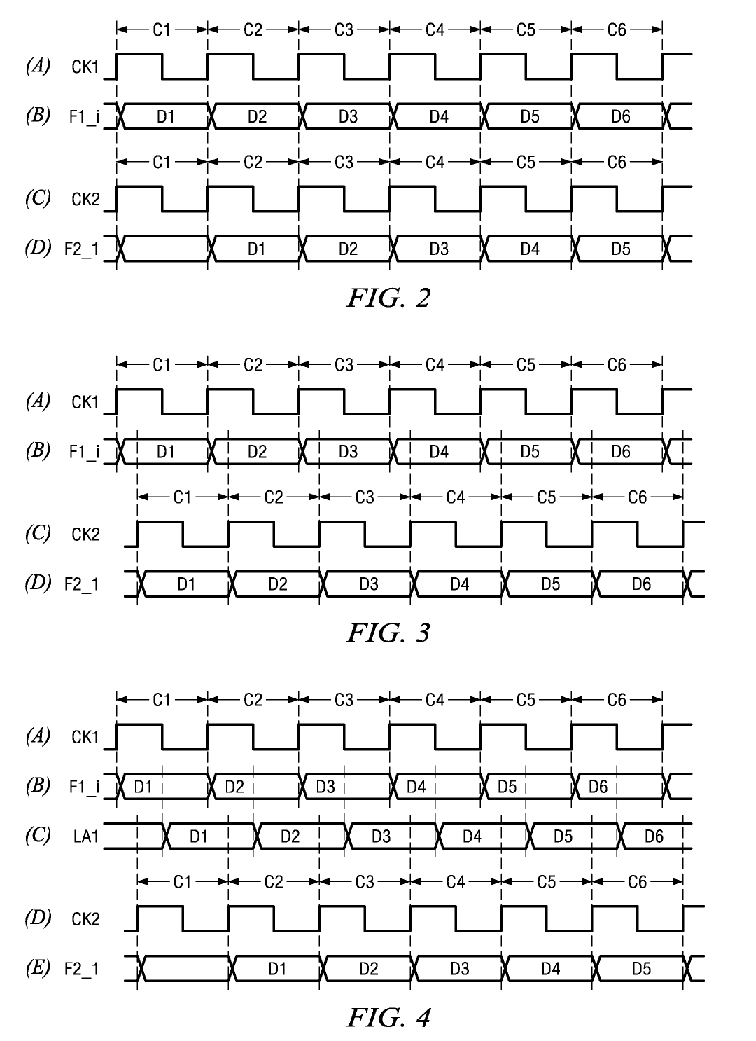

In the second inspection mode, scan chains SC1-SCm are coupled in series by selector circuits SL2-SLm. Latch circuits (LA1-LAm) of data hold unit 30 are inserted between the respective pairs of serially coupled scan chains. Inspection data Sin generated by the inspection device not shown are input to scan chain SC1 through inspection data generator unit 10. The flip-flops of the respective scan chains are set to the second inspection mode using an enable signal, wherein the inspection data are shifted serially through scan chains SC1-SCm, which are coupled in series. Once desired inspection data are set at the respective flip-flops, the flip-flops of the scan chains are first set to the normal operating mode, and the normal operation is carried out for the desired clock cycle duration. Subsequently, the flip-flops are brought back to the inspection mode, and the response data held at the respective flip-flops are shifted serially. The response data output serially from last-stage scan chain SCm are taken into the inspection device through latch circuit LAm and selector circuit 40. The inspection data input and the response data taken in are compared at the inspection device in order to determine whether or not the semiconductor integrated circuit is performing desired operations. Here, the inspection data hold operation carried out by data hold unit 20 will be explained in detail with reference to FIGS. 2-4.

FIGS. 2 and 3 are diagrams for illustrating problems that occur when data hold unit 20 is not provided. FIG. 2 shows operations carried out when the phases of clock signals CK1 and CK2 match, and FIG. 3 shows operations carried out when the phase of clock signal CK2 lags that of clock signal CK1.

In the example shown in FIG. 2, the phases of clock signals CK1 and CK2 match (FIG. 2 (A), (C)). That is, clock signals CK1 and CK2 rise at the same timing within the same clock cycle. The flip-flops of scan registers SC1 and SC2 latch input data almost at the same timing.

For example, data D1 are latched into last-stage flip-flop F1_{—}i of scan register SC1 at the rise of clock cycle C1, and data D2 at the rise of clock cycle C2 (FIG. 2 (B)). Data D1 held in flip-flop F1_{—}i are latched into first-stage flip-flop F2_1 of scan register SC2 at the time of rise of clock cycle C2 (FIG. 2 (D)).

As described above, when the phases of clock signals CK1 and CK2 match, data latched into flip-flop F1_{—}i during a certain cycle are latched into flip-flop F2_1 during the next cycle. That is, the data are shifted from scan register SC1 to SC2 according to the sequence the clock cycles.

On the other hand, in the example shown in FIG. 3, phase of clock signal CK2 lags that of clock signal CK1 (FIG. 3 (A), (C)). That is, clock signal CK2 rises after clock signal CK1 of the same clock cycle. The flip-flops of scan registers of scan register SC2 latch input data with a delay after those of scan register SC1.

For example, data D1 are latched into last-stage flip-flop F1_{—}i of scan register SC1 at the rise of clock cycle C1, and data D2 at the rise of clock cycle C2 (FIG. 3 (B)). Data D1 held in flip-flop F1_{—}i are latched into first-stage flip-flop F2_1 scan register SC2 at the rise of clock cycle C1, and data D2 held in flip-flop F1_{—}i are latched at the rise of clock cycle C2 (FIG. 3 (D)).

As described above, when the phase of clock signal CK2 lags that of clock signal CK1, data latched into flip-flop F1_{—}i during a certain cycle are also latched into flip-flop F2_1 during the same cycle. That is, the data which are supposed to be latched during the next clock cycle are taken into flop-flop F2_1. Thus, the data which were latched into flop-flop F2_1 immediately before the shifting of the data are overwritten by the data shifted to flip-flop F1_1 during the first clock cycle, which creates the problem that a portion of the data to be transferred to the inspection device is missing, and the sequence of the data with respect to the clock cycles is altered.

Accordingly, the semiconductor integrated circuit in accordance with a preferred embodiment of the present invention is provided with data hold unit 20 between the serially coupled scan registers.

FIG. 4 is a diagram illustrating a data shift operation via data hold unit 20.

Latch circuit LA1 of data hold unit 20 is provided between last-stage flip-flop F1_{—}i of scan register SC1 and first-stage flip-flop F2_1 of scan register SC2. While the data in the preceding stage are latched into flip-flop F1_{—}i synchronously with the rise of clock signal CK1 (FIG. 4 (A)) (FIG. 4 (B)), the data in flip-flop F1_{—}i are latched into latch circuit LA1 synchronously with the fall of clock signal CK1 (FIG. 4 (C)).

Because the data are latched at latch circuit LA1, the data from the preceding cycle are input continuously to flip-flop F2_1 for a while even after data a new clock cycle are latched into flip-flop F1_{—}i. That is, the data which should be latched at flip-flop F2_1 are input continuously to flip-flop F2_1 for a longer period of time. For example, when the duty ratio (ratio of the high-level period to the low-level period) of clock signal CK1 is 1:1, the period during which the data are input to flip-flop F2_1 is extended half a cycle.

Therefore, even when the phase of clock signal CK2 slightly lags that of clock signal CK1 (FIG. 4 (D)), correct data are latched at flip-flop F2_1 (FIG. 4 (E)). It is desirable to control the phase difference between clock signal CK1 and clock signal CK2 to become smaller than a half cycle.

As explained above, according to the semiconductor integrated circuit in accordance with a preferred embodiment of the present invention, scan chains SC1-SCm are coupled in series when in the second inspection mode, and the inspection data are supplied to its first-stage scan chain SC1. Although the supplied inspection data are shifted through the respective scan chains based on the clock signals with different phases, when they are shifted across the scan chains which are coupled in series, they are held by data hold unit 20. That is, the inspection data are held by data hold unit 20 in sequence while they are being shifted between the serially coupled scan chains such that the inspection data are shifted across the scan chains according to the sequence of the clock cycles of the clock signals (CK1-CKm). More specifically, the inspection data output from scan chain SCr (r=1 to m−1) at the rise of clock signal CKr are held by latch circuit LAr of data hold unit 20 synchronously with the fall of clock signal CKr and output to subsequent-stage scan chain SCr+1.

Therefore, even when multiple scan chains, which are used to shift the inspection data based on different clock signals, are coupled in series, the scan path can be inspected appropriately without any data shift errors between the scan chains.

In addition, according to the semiconductor integrated circuit in accordance with a preferred embodiment of the present invention, the response data output from scan chains SC1-SCm when in the first inspection mode are input to response data processing unit 30 without involving data hold unit 20.

When the response data are transferred through data hold unit 20, 1 response datum from scan chain SCn is held by data hold unit 20 at a point within the 1 clock cycle during which the 1 response datum is output. With reference to the example shown in FIG. 4, data output from scan chain SC1 are held by latch circuit LA1 when approximately a half cycle has passed after the data were output. In this case, because the setup time present before the data are held at data hold unit 20 becomes shorter than the 1 clock cycle, the room for the setup time at data hold unit 20 is reduced, and the timing requirement for the data hold operation at data hold unit 20 becomes stricter. On the other hand, in the present embodiment, because the response data are input to response data processing unit 30 without involving data hold unit 20, the timing requirement restriction imposed on data hold unit 20 is eliminated. Therefore, the data shifting speed in the first inspection mode can be increased, which contributes to a reduction in the inspection time.

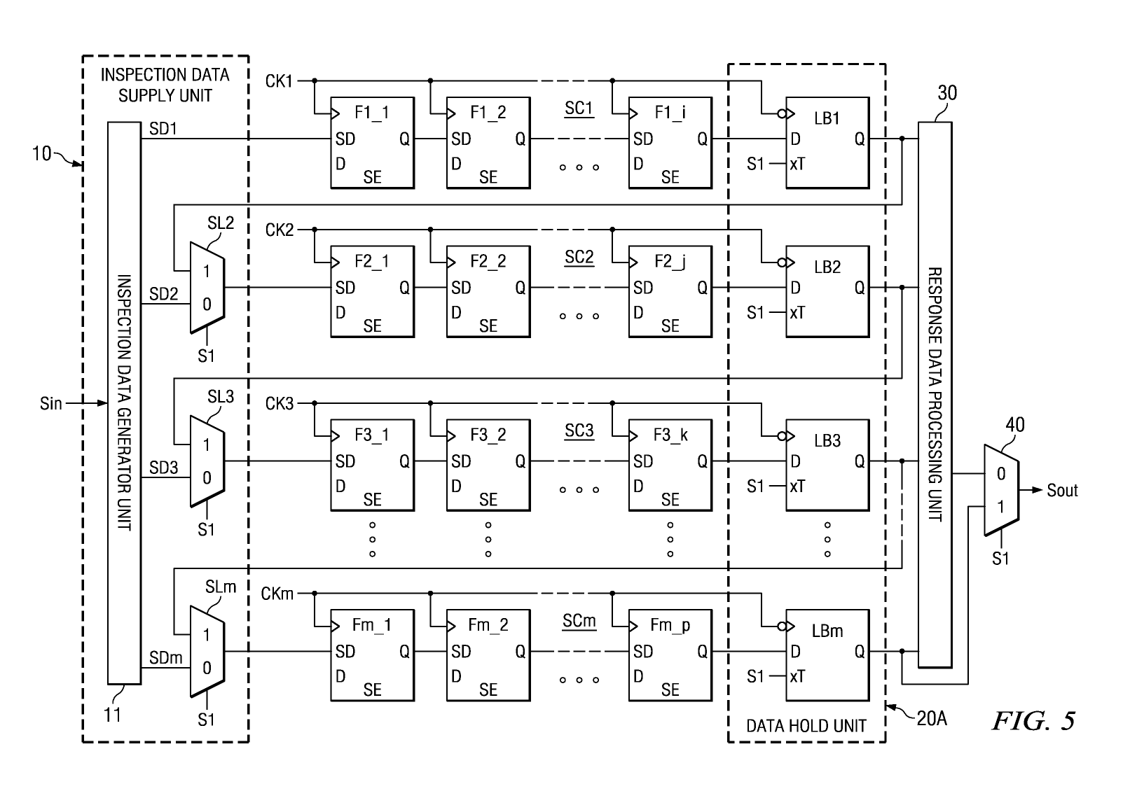

FIG. 5 is a diagram illustrating an example configuration of the semiconductor integrated circuit in accordance with a preferred embodiment of the present invention. In the semiconductor integrated circuit shown in FIG. 5, data hold unit 20 of the semiconductor integrated circuit shown in FIG. 1 is replaced with data hold unit 20A, and response data processing unit 30 takes response data from scan chains SC1-SCm as inputs through data hold unit 20A. The other portion of the configuration is identical to that of the semiconductor integrated circuit shown in FIG. 1.

Data hold unit 20A holds the inspection data shifted between the scan chains at similar timing to that of data hold unit 20 in order to avoid any data shift errors when in the second inspection mode, but it does not perform the holding of the data when in the first inspection mode. That is, it outputs inspection data input from the preceding-stage scan chain to the subsequent-stage scan chain transmissively when in the second inspection mode.

In the example shown in FIG. 5, data hold unit 20A has latch circuits LB1-LBm. For latch circuits LB1-LBm, a data hold operation control function is added to latch circuits LA1-LAm shown in FIG. 1. That is, latch circuits LB1-LBm-1 hold data in similar fashion to latch circuits LA1-Lam-1 when in the second inspection mode, and it outputs the response data from the respective scan chains transmissively when in the first inspection mode according to the inspection mode control signal S1 that is input to enable terminal xT.

According to the semiconductor integrated circuit shown in FIG. 5, because data hold unit 20A outputs the response data transmissively when in the first inspection mode, even when the response data are input to response data processing unit 30 through data hold unit 20A, the timing requirement is not stricter. Therefore, like the semiconductor integrated circuit shown in FIG. 1, the data shifting speed in the first inspection mode can be increased. In addition, because data hold unit 20A holds the inspection data in a similar fashion to data hold unit 20 when in the second inspection mode, the scan path can be inspected without any data shift errors.

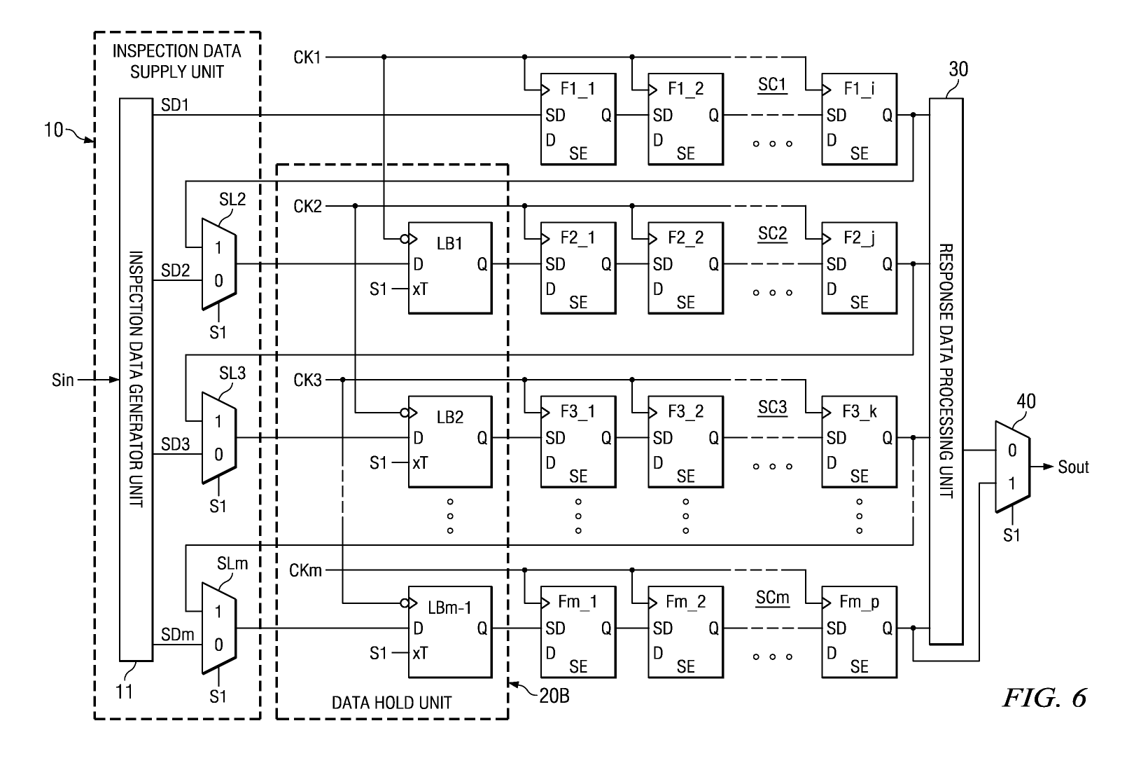

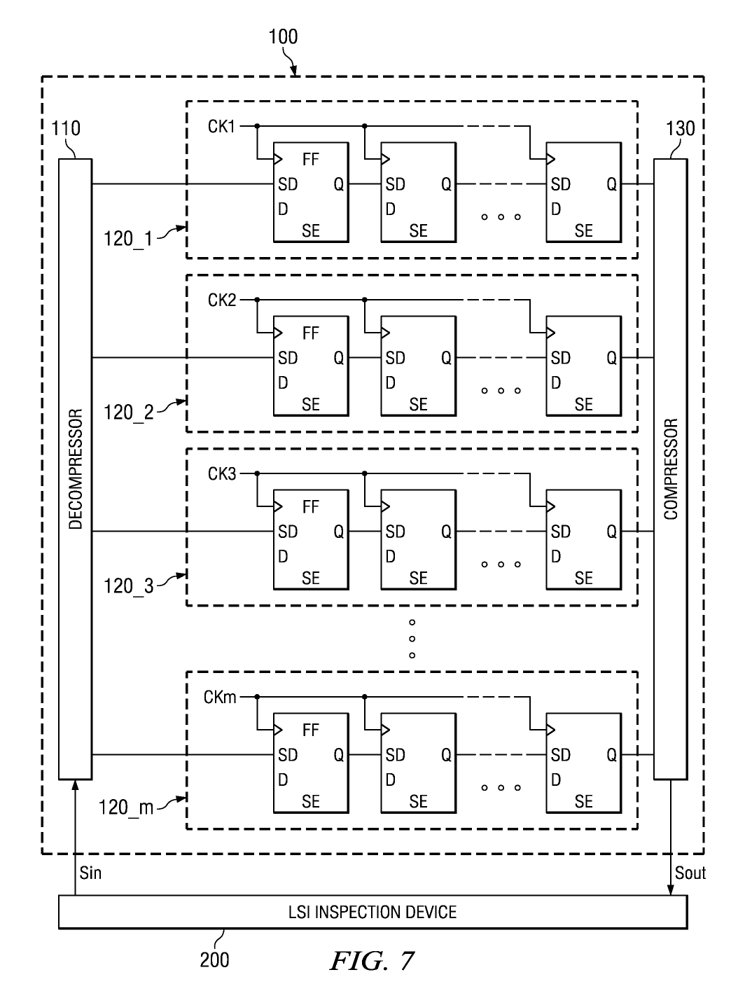

FIG. 6 is a diagram illustrating an example configuration of the semiconductor integrated circuit in accordance with a preferred embodiment of the present invention. In the semiconductor integrated circuit shown in FIG. 6, data hold unit 20 of the semiconductor integrated circuit shown in FIG. 1 is replaced with data hold unit 20B, and respective selector circuits (SL2-SLm) of inspection data supply unit 10 are provided on the input side of data hold unit 20B. The other portion of the configuration is identical to that of the semiconductor integrated circuit shown in FIG. 1.

Data hold unit 20B is similar to data hold unit 20A shown in FIG. 5 in that while it holds the data shifted between the scan chains when in the second inspection mode, it outputs the input data transmissively when in the first inspection mode.

For example, data hold unit 20B has latch circuits LB1-LBm-1 which are equipped with a data hold operation control function similar to that of the components indicated by the same symbols in FIG. 5. That is, latch circuits LB1-LBm-1 hold data in similar fashion to latch circuits LA1-LAm-1 when in the first inspection mode, and it outputs the response data from the respective scan chains transmissively when in the first inspection mode according to inspection mode control signal S1 that is input to enable terminal xT.

Here, in the example shown in FIG. 6, latch circuit LBm is omitted, and the data output from scan chain SCm are input to selector circuit 40 as-is.

Selector circuit SLq (q=2-m) of inspection data supply unit 10 is provided on the path that connects scan chain SCq-1 to scan chain SCq on the input side of latch circuit LBq-1. Selector circuit SLq selectively outputs inspection data SDq of scan chain SCq, which are generated by inspection data generator unit 11, when in the first inspection mode; and it selectively outputs the shifted inspection data output from scan chain SCq-1.

Response data processing unit 30 takes the response data from scan chains SC1-SCm as input on the input side of selector circuit SL2-SLm, without involving data hold unit 20, and compresses the data.

According to the semiconductor integrated circuit shown in FIG. 6, because data hold unit 20B outputs the response data transmissively when in the first inspection mode, inspection data SDq input to data hold unit 20B via selector circuit SLq (q=2-m) are then directly input to scan chain SCq without being held by data hold unit 20B. Therefore, in the present embodiment, too, the inspection can be carried out normally when in the first inspection mode. In addition, because a similar inspection to that by data hold unit 20 is carried out by data hold unit 20B when in the second inspection mode, the scan path can be inspected without any data shift errors. Moreover, because the response data are input to response data processing unit 30 without involving data hold unit 20B, the data shifting speed in the first inspection mode can be increased, as with the semiconductor integrated circuit shown in FIG. 1.

In the case of the semiconductor integrated circuits shown in FIGS. 1 and 5, although a latch circuit (LAm or LBm) is provided on the output side of scan chain SCm, because no data shift errors occur when the data are not held on the output side of scan chain SCm, this latch circuit can be omitted. Although examples in which the inspection data compressed by the inspection device are restored by inspection data generator unit 11 are given, the present invention is not restricted to this. For example, it is also feasible that a pseudo-random pattern to be generated at inspection data generator unit 11, and that the pattern be supplied to the respective scan chains as inspection data.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a plurality of scan chains, wherein each scan chain shifts inspection data based at least on part on one of a plurality of clock signals;
an inspection data supply unit that is coupled to each supply chain, wherein the inspection data supply unit that supplies the inspection data to each of the scan chains in a first inspection mode and that couples each scan chains together in series with one another to form a single chain in a second inspection mode; and
a data hold unit that is coupled to each scan chain, wherein the data hold unit holds the inspection data being shifted between the scan chains in sequence.

2. The apparatus of claim 1, wherein each scan chain further comprises a plurality of flip-flops coupled in series with one another.

3. The apparatus of claim 1, wherein the data hold unit further comprises a plurality of latches that are coupled in series with one another, and wherein each latch is coupled to at least one scan chain.

4. The apparatus of claim 1, wherein the apparatus further comprises a processing unit that is coupled to each scan chain and to the data hold unit.

5. The apparatus of claim 1, wherein the inspection data supply unit further comprises:
a data generator that is adapted to provide inspection data to each scan chain; and
a plurality of multiplexers, wherein each multiplexer is coupled between the data generator and at least one of the scan chains, and wherein the multiplexers are arranged to couple to scan chains in series with one another to form a single chain in the second inspection mode.

6. An apparatus comprising:
a first scan chain that is adapted to shift inspection data based at least in part on a first clock signal;
a second scan chain that is adapted to shift the inspection data based at least in part on a second clock signal;
an inspection data supply unit that is coupled to the first and second scan chains, wherein the inspection data supply unit that supplies the inspection data to each of the first and second scan chains in a first inspection mode and that couples the first and second scan chains together in series with one another to form a single chain in a second inspection mode; and
a data hold unit that is coupled to the first and second scan chains, wherein the data hold unit holds the inspection data being shifted between the scan chains in sequence.

7. The apparatus of claim 6, wherein the data hold unit further comprises a latch that is coupled between the inspection data supply unit and the second scan chain, wherein the latch is clock by the first clock signal.

8. The apparatus of claim 7, wherein the inspection data supply unit further comprises:
a data generator that is coupled to the first scan chain;
a multiplexer having a first input terminal, a second input terminal, and an output terminal, wherein the first input terminal is coupled to the first scan chain, and wherein the second input terminal is coupled to the data generator, and the output terminal is coupled to the latch.

9. The apparatus of claim 6, wherein the data hold unit further comprises:
a first latch that is coupled to the first scan chain and that is clocked by the first clock signal; and
a second latch that is coupled to an output of the first latch and the second scan chain and that is clocked by the second clock signal.

10. The apparatus of claim 9, wherein the inspection data supply unit further comprises:
a data generator that is coupled to the first scan chain;
a multiplexer having a first input terminal, a second input terminal, and an output terminal, wherein the first input terminal is coupled to the first latch, and wherein the second input terminal is coupled to the data generator, and wherein the output terminal is coupled to the second scan chain.
